(19) United States
(12) Patent Application Publication
(10) Pub. No.: US 2005/0173741 A1
(43) Pub. Date: Aug. 11, 2005

(54) Top drain MOSFET with thickened oxide at trench top

(75) Inventor: Kyle Spring, Temecula, CA (US)

Correspondence Address: OSTROLENK FABER GERB & SOFFEN, 1180 AVENUE OF THE AMERICAS, NEW YORK, NY, 100368403, US

(73) Assignee: International Rectifier Corp.

(21) Appl. No.: 11/052,458

(22) Filed: Feb. 7, 2005

Related U.S. Application Data
(60) Provisional application No. 60/543,439, filed on Feb. 9, 2004.

(51) Int. Cl. H01L 29/76

(52) U.S. Cl. 257/288

(57) ABSTRACT

A top drain MOSFET has active trenches with an enlarged width at the top of each trench which has a thicker oxide than the gate oxide adjacent the channel region. The thicker oxide at the top of the trench reduces Q_{gd}. The thicker oxide at the top of the active trench also reduces the electronic field in the drain drift region.

### RELATED APPLICATION

The present application is based on and claims benefit of U.S. Provisional Application No. 60/543,439 filed Feb. 9, 2005; and copending application Ser. No. ______ , filed ______ entitled TOP DRAIN MOSFET in the name of Daniel M. Kinzer (IR-2471) assigned to the assignee of the present application, the disclosure of which is incorporated herein by reference.

### BACKGROUND OF THE INVENTION

Vertical conduction MOSgated devices are well known. By MOSgated device is meant a MOSFET, IGBT or the like. By a vertical conduction device is meant a device in which current conduction through the die is from one surface of the die, through the thickness of the die, and to its opposite surface. By die is meant a single die or chip which is singulated from a wafer in which all die within the wafer are simultaneously processed before singulation. The terms die, wafer and chip may be interchangeably used.

FIG. 1 shows a known type of vertical conduction MOSFET, using a trench type technology. FIG. 1 is a cross-section through a MOSFET die and shows one cell of a device in which a plurality of identical such cells are laterally disposed relative to one another. These cells may be parallel stripes, or closed cells of circular, rectangular, square, hexagonal or any other polygonal topology and may appear identical in a cross-sectional view.

In FIG. 1, the wafer or die has an N⁺ substrate 20 of monocrystalline silicon (float zone, for example) which has a top epitaxially grown N type silicon layer, which first includes drift region 21. A P type base implant and diffusion into the epitaxial layer 21 forms the P base region 22, and an N type implant and diffusion forms the N⁺ source region layer 23. Spaced trenches 24 and 25 (which may be stripes or cellular) are formed in the top of the wafer. A silicon dioxide or other insulation liner has a thick bottom section 30 and a thin vertical gate section 31 lines the trench 25. A conductive polysilicon gate electrode 32 then fills the trench 25. A top oxide segment 33 completes an insulated enclosure for gate polysilicon 32. A source electrode 40 is then deposited atop the wafer or chip and fills trench 24 to short the N⁺ source 23 to the P base, thereby to disable the parasitic bipolar transistor formed by regions 21, 22 and 23. A conductive drain electrode 41 is formed on the bottom of the die.

In operation, the application of a gate turn-on potential to gate 32 relative to source 40 will invert the concentration at the surface of P base 22 which lines oxide 31, thus permitting the flow of majority carriers from drain 41 to source 40.

### BRIEF DESCRIPTION OF THE INVENTION

Copending application Ser. No. ______ (IR-2471) discloses a MOSgated device having reversed source and drain electrodes as compared to the conventional MOSFET of FIG. 1. Thus, as shown in FIGS. 2 and 3, a drain structure is formed in the top (junction receiving side) of the chip, and the source is at the bottom of the chip. Spaced vertical gate trenches are formed into the top of the die or wafer. A base or channel invertible region is disposed adjacent the trench wall and is buried beneath an upper drift region. A further trench or cell disposed between the gate trenches permits the formation of a conductive region at its bottom to short the buried P base to the N⁺ substrate. This reversal of functions produces a significant improvement in R*Q_{sw} and R*A over current technology (60% and 26% respectively). It further enables a four times reduction in gate resistance and enables multiple packaging options for the copackaging of die.

FIGS. 2 and 3 show the top drain FET disclosed in application Ser. No. ______ (IR-2471).

FIG. 2 is a cross-section of one cell of the prior art top drain device. The device is shown as an N channel device, but all conductivity types can be reversed to produce a P channel device. Like the structure of FIG. 1, the die or wafer has an N⁺ substrate 50 (a source region) which has an N⁻ type epitaxial silicon layer formed on its upper surface. A P type implant and diffusion forms the buried P base or channel 51, and an N⁺ implant and diffusion forms the drain region layer 52, into the top of N drift region layer 53. Three trenches 60, 61 and 62 of a plurality of such trenches are formed into the top of the die or wafer, forming the single cell shown. The outer trenches 60 and 62 are gate trenches and have vertical silicon dioxide (or other insulation) bottom layers 63 and 64 respectively, and vertical gate oxide layers 65 and 66 respectively. Conductive polysilicon layers 67 and 68 are formed to be contained within trenches 60 and 62 and insulated from the surrounding silicon by oxide layers 63, 65 and 64, 66 respectively. Oxide fillers 69 and 70 then fill the trenches 60 and 62 above polysilicon gates 67 and 68 respectively.

The central trench 61 receives a conductive layer 71 at its bottom to connect (short) the P base 51 to the N⁺ substrate 50. The remainder of the trench 61 is then filled with insulation oxide 72.

A drain electrode 75, which may be aluminum with a small silicon content is formed over the top of the die or wafer, and a conductive source electrode 76 is formed on the wafer or die bottom.

To turn the device of FIG. 2 on, a potential applied to gate 67, 68 relative to substrate 50 will form an inversion region along the surfaces of base regions 51 to enable the conduction of majority carriers (electrons) from top drain 75 to bottom source electrode 76. Note again that all conductivity types can be reversed to form a P channel device, rather than the N channel device shown.

The effect of the novel structure of FIG. 2 permits a reduced overlap between the drain drift region 53 and gates 67, 68 producing a lower Q_{gd} and Q_{sw} as compared to that of FIG. 1. Further, a thicker oxide 65, 66 can be used between the gates 67, 68 and drain drift region 53, again reducing Q_{gd} and Q_{sw}. Further, the cell density may be greater than that of FIG. 2 to reduce R_{DSON}, and the elimination of the JFET effect further reduces R_{DSON}.

In general, the Figure of Merit (FOM) of the structure of the top drain of FIG. 2 is considerably reduced as compared to that of FIG. 1 for an equivalent design.

Referring next to the prior art device of FIG. 3, components similar to those of FIG. 2 have similar identifying numerals. However, it will be noted that in FIG. 3, contact 71 is formed of a conductive silicide. Further, an N⁺ implant 90, carried out before insulation plug 72 is formed ensures a good connection for shorting the source substrate 50 to the P channel region 51.

Further, FIG. 3 shows the use of a silicide layer 91 atop the gate polysilicon 67 to reduce lateral gate resistance.

In FIG. 3, the gate oxide 65 has a single thickness in the active trench along the channel or base region 51. For this reason, the poly recess, etch must be precisely controlled in order to control and minimize the capacitance between gate 68 and drain 53 to minimize the charge Q_{gd.} Minimizing Q_{gd} is important to prevent false turn on due to a high dv/dt between drain and source which could produce a gate voltage which is higher than the device threshold voltage.

It would be desirable to provide a top drain structure in which the polysilicon recess can terminate closer to the silicon surface while reducing Q_{gd}; and to decrease the gate resistance Rg and to reduce the electric field in the drain drift region to improve manufacturing yield and to extend the useful drain voltage rating to higher voltages.

### BRIEF SUMMARY OF THE INVENTION

In accordance with the invention, the oxide lining the active trench is increased in thickness at a widened trench portion at the top section of the trench, while a thinner gate oxide lines the trench from the trench bottom to the upper thickened region. More specifically, the thin oxide can be about 450 Å thick (for a 20 volt device) and the thicker top oxide will have a thickness greater than about 1000 Å, preferably 1500 Å for the 20 volt device.

### BRIEF DESCRIPTION OF THE DRAWINGS

FIG. 1 is a cross-section of one cell of a prior art trench type MOSFET.

FIGS. 2 and 3 are cross-sections of the top drain type MOSFETs shown in copending application Ser. No. ______ (IR-2471).

FIG. 4 is a cross-section of a top drain MOSFET employing a thickened oxide top segment in the active trench of a top drain MOSFET in accordance with the invention.

### DESCRIPTION OF THE DRAWINGS

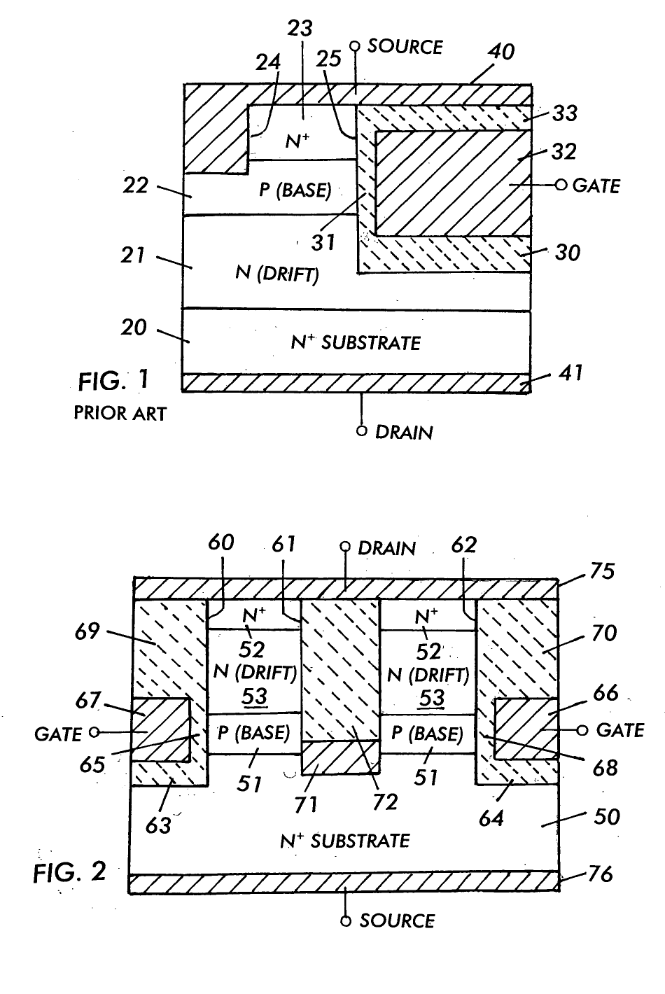

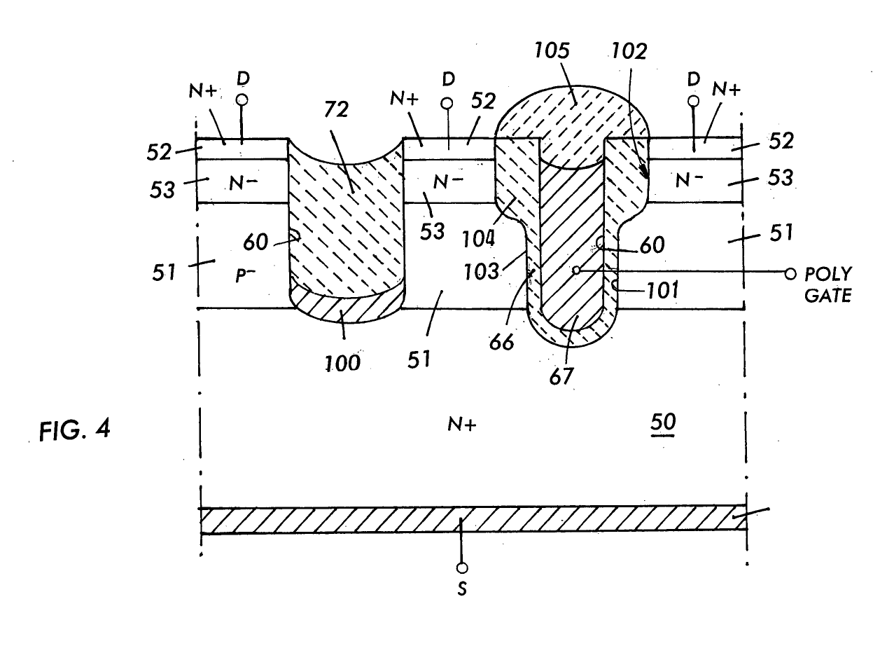

FIGS. 1, 2 and 3 have been previously described. The device of the invention is shown in FIG. 4 and components similar to those of FIGS. 1, 2 and 3 are given the same identifying numeral.

It will be noted that the device of FIG. 4 is shown as an N channel device, but could be a P channel device by a reversal of the conductivity types shown. Further only 2 of a large number of parallel, identical trenches are shown in a repeating pattern in which all active trenches 60 are alternated with trenches 62 which carry conductive contacts 100 at their bottom to connect the P base regions 51 to the N⁺ source (substrate) region 50.

The geometry of active trench 60 is modified in accordance with the invention to have a small width (or diameter) dimension segment 101 and a larger upper dimension segment 102. Segment 101 is lined with a grown gate oxide 103 of thickness of about 450 Å to a point just short of the upper limit of the invertible channel region in base region 51. Segment 102 is lined with a grown oxide 104 of thickness greater than about twice the thickness of oxide 103, and about 1500 Å for a 20 volt device.

The conductive polysilicon 67 can now be closer to the top of the silicon die or wafer and is capped with an oxide cap 105.

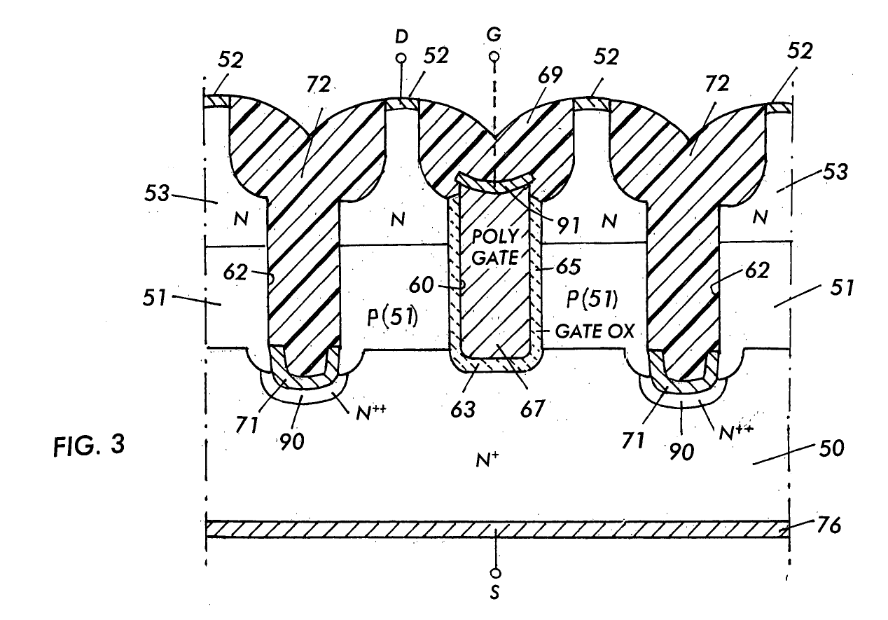

Thus, the invention shown in FIG. 4 uses a thicker oxide 103 near the top of trench 60 and a thinner oxide 102 extending from region 103 to the bottom of trench 60. With this construction the polysilicon recess below the top silicon surface can vary in height without a corresponding variation in Q_{gd} as occurs in the prior design of FIG. 2. Furthermore, having the polysilicon recess closer to the top of the silicon results in a lower effective gate resistance. Also, the thicker top oxide 103 helps to reduce the electric field in the drain drift region 53 which will improve yield, reliability, and extends the useful drain voltage rating to higher voltages.

Any desired process can be used to obtain the structure of FIG. 4. Thus, a shallow trench etch of 0.25 to 1.0 μm can first form the larger top trench portion 101. This can be followed by a thick grown oxidation step of thickness 400 Å to 1500 Å. The bottom oxide of this first shallow etch opening is then removed by an anisotropic etch or by any desired process. A second trench etch is then carried out to form the narrower trench opening 101 to a further depth of 0.1 to 0.5 μm, depending on the desired drain voltage of the device to be formed, and the thin oxide layer 102 is thermally grown. The composite trench is then filled with conductive polysilicon which is later etched to expose the mesa between trenches with a slight non-critical under etch. The cap oxide 105 is then formed as desired.

If desired the grown oxide step to form thick oxide 103 can be replaced by a deposited oxide to preserve the mesa width which allows a reduced cell pitch and a lowered on resistance for the final device.

Although the present invention has been described in relation to particular embodiments thereof, many other variations and modifications and other uses will become apparent to those skilled in the art. It is preferred, therefore, that the present invention be limited not by the specific disclosure herein, but only by the appended claims.

1. An active trench structure for a top drain MOSFET device; said MOSFET device comprising a semiconductor wafer having a top and bottom surface; said wafer having a substrate of one conductivity type extending from said bottom surface, a channel layer of the other conductivity type disposed atop said substrate, and a drain drift region layer of said one conductivity type disposed atop said channel; said active trench structure comprising a trench extending into said top surface and through said drain drift region layer and said channel layer and into said substrate; said trench having an enlarged width portion at the top thereof which extends from the top of said channel layer through the full thickness of said drain drift region and to said top surface; the interior of the length of said trench from the bottom of said enlarged width portion to the bottom of said trench having a gate oxide liner of a first thickness; the interior of the length of said enlarged width portion being lined with an oxide of a second thickness which is at least twice the thickness of said first thickness; and a conductive polysilicon mass filling the interior of said trench and terminating at a surface near to said top surface.

2. The device of claim 1, wherein said polysilicon mass has a constant width along its full length.

3. The device of claim 1, which includes a drain electrode connected to said top surface, a source electrode connected to said bottom surface and a gate electrode connected to said polysilicon mass.

4. The device of claim 1, which includes a high concentration drain contact layer disposed atop said drift region layer.

5. The device of claim 2, which includes a drain electrode connected to said top surface, a source electrode connected to said bottom surface and a gate electrode connected to said polysilicon mass.

6. The device of claim 3, which includes a high concentration drain contact layer disposed atop said drift region layer.

7. The device of claim 5, which includes a high concentration drain contact layer disposed atop said drift region layer.
